(19) United States
(12) Patent Application Publication
(10) Pub. No.: US 2007/0246199 A1
(43) Pub. Date: Oct. 25, 2007

(54) Heat dispensing assembly

(76) Inventors: Shn-Yung Lee, Tainan City (TW); Shueei-Muh Lin, Tainan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/409,980

(22) Filed: Apr. 25, 2006

(51) Int. Cl. H05K 7/20

(52) U.S. Cl. 165/122; 165/80.4; 361/698; 361/697

(57) ABSTRACT

A heat dispensing assembly includes a centrifugal fan eccentrically installed in a base which has an outlet defined in a side thereof and a cover is mounted on the base. A plurality of fins are located around the centrifugal fan and a heat exchanging tube is received in the base and a heat exchangeable substance is received in the heat exchanging tube. A heat source is connected to the heat exchanging tube and the air flows generated by the centrifugal fan bring heat conducted to the fins from the heat exchangeable substance away from the outlet of the base.

### FIELD OF THE INVENTION

The present invention relates to a heat dispensing assembly with axial fan and heat exchanging tube for quickly removing heat from heat source.

### BACKGROUND OF THE INVENTION

A conventional heat dispensing device 10 used for removing heat from heat source such as CPU of computers to prevent from damage to the electronic parts due to high temperature is shown in FIG. 1 and generally includes an axial fan and a radiator 2 which includes a base 21 and a plurality of fins 22 extend from a top of the base 21. The fins 22 are arranged such that a passage 23 is defined between two groups of the fins 22. The radiator 2 is put on the heat source 3 and the axial fan 1 is located above the radiator 2 such that air flows blow thorough the gaps between the fins 22 and bring the heat of the heat source 3 via the passage 23.

Due to the size of the electronic appliance becomes more compact than ever, the heat dispensing device 10 is required to be thin and small. However, the axial fan 1 is installed above the radiator 2 and includes a motor 11 to drive the blades 12 of the fan 1 so that the thickness of the whole heat dispensing device cannot meet the requirement for the modern electronic appliance. Besides, the air flows generated by the axial fan 1 is swirl flows which cannot reach to every gaps between the fins 22 and the flows cannot reach the center of the radiator 2 either so that the efficiency for bringing heat out from the heat source is less satisfied.

The present invention intends to provide a heat dispensing assembly which includes a hollow heat exchanging tube in which a heat exchangeable substance is received so that the heat can be more efficiently removed from the heat source by air flows.

### SUMMARY OF THE INVENTION

The present invention relates to a heat dispensing assembly which comprises a base having an outlet is defined in a side of the base. A cover is mounted on the base and has an inlet. A centrifugal fan is eccentrically received in the base and includes a blade unit which is driven by a motor. A heat exchanging unit has a plurality of fins located around the centrifugal fan. A heat exchanging tube is received in the base and a heat exchangeable substance is received in the heat exchanging tube.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is an exploded view to show a conventional heat dispensing device;

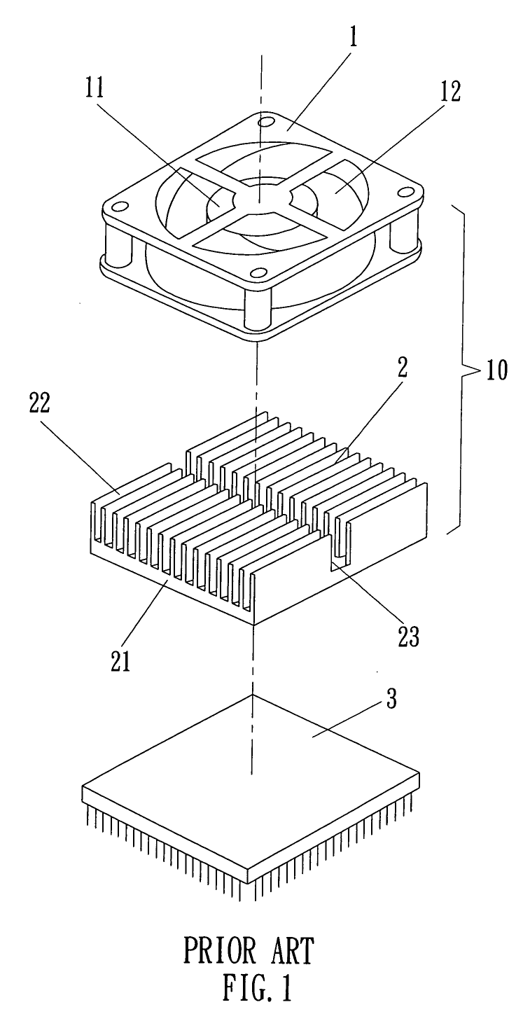

FIG. 2 shows the air flows generated by the axial fan and the radiator of the conventional heat dispensing device;

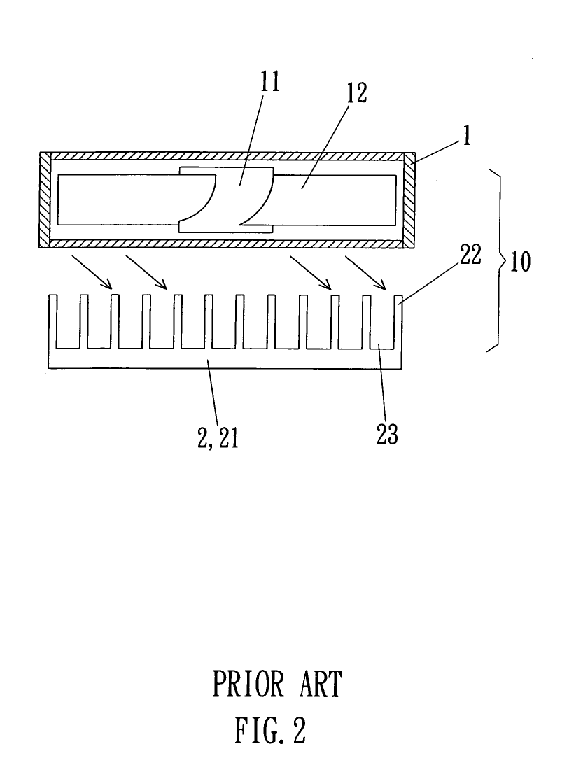

FIG. 3 is an exploded view to show the heat dispensing assembly of the present invention;

FIG. 4 is a top view to show the position of the fins and the heat exchanging tube of the heat dispensing assembly of the present invention;

FIG. 5 is a cross sectional view to show the heat dispensing assembly of the present invention;

FIG. 6 is a perspective view to show the heat dispensing assembly of the present invention;

FIG. 7 shows another embodiment of the heat dispensing assembly of the present invention;

FIG. 8 is a cross sectional view of the heat dispensing assembly in FIG. 7;

FIG. 9 shows yet another embodiment of the heat dispensing assembly of the present invention;

FIG. 10 shows a further embodiment of the heat dispensing assembly of the present invention;

FIG. 11 shows that the heat exchanging tube is composed of two parts which extend through the fins, and

FIG. 12 shows that the heat exchanging tube is composed of two parts which are engaged with notches in the fins.

### DETAILED DESCRIPTION OF THE PREFERRED EMBODIMENT

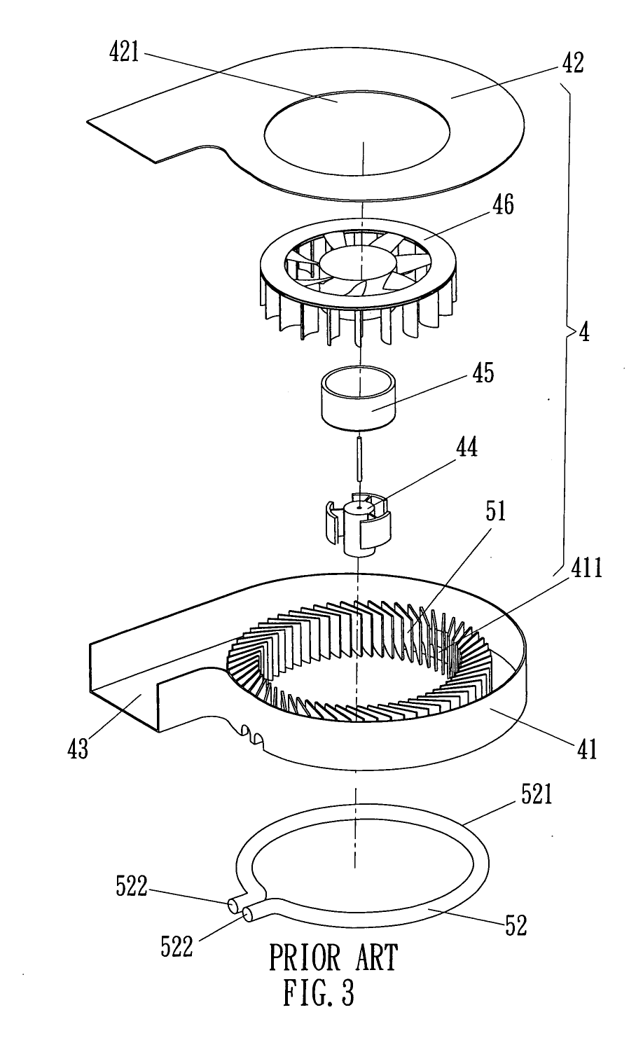

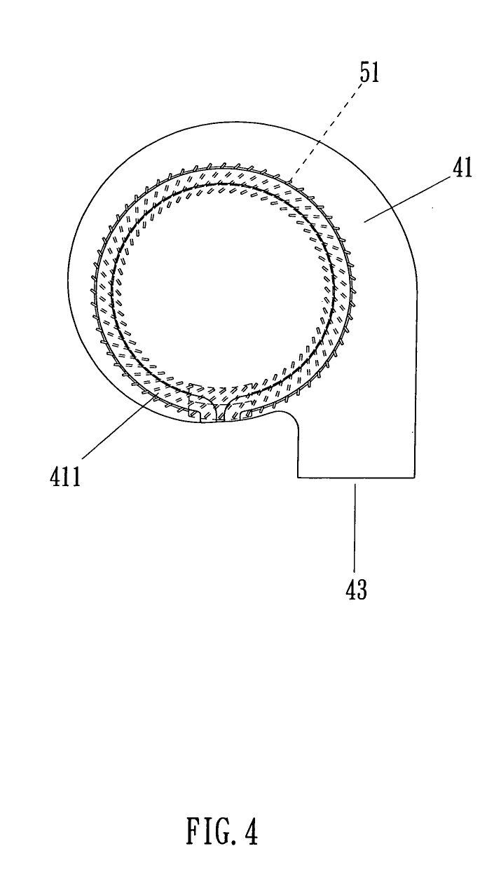

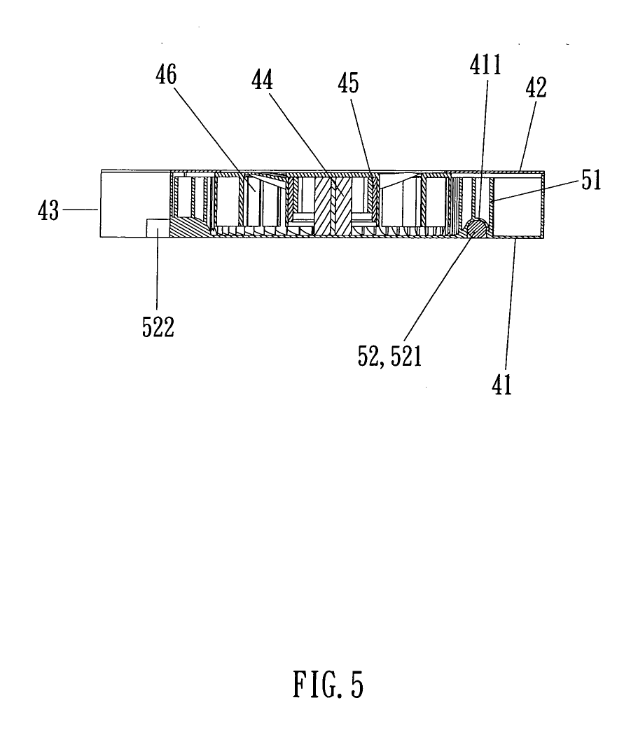

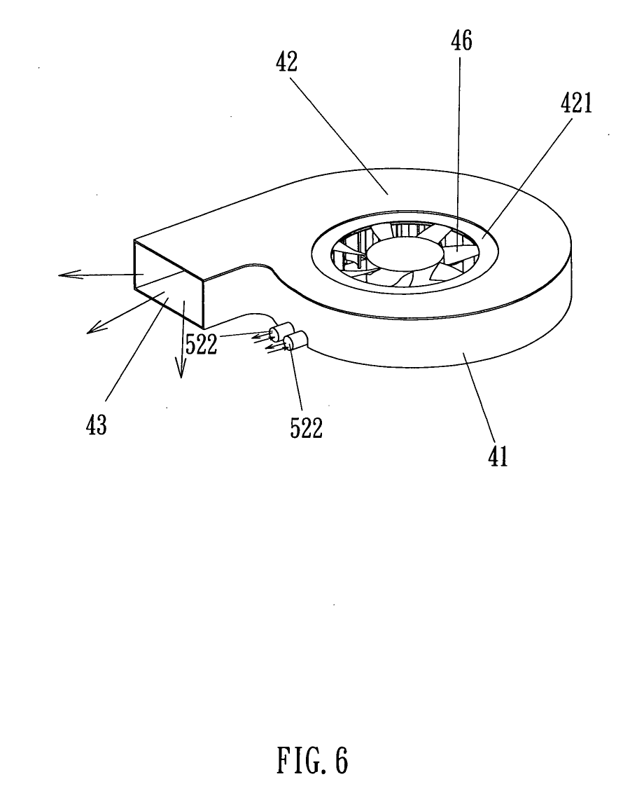

Referring to FIGS. 3 to 6, the heat dispensing assembly of the present invention comprises a base 41 having a groove 411 defined in an inner top thereof and an extension tube extends from a side of the base 41 and an outlet 43 is defined through the extension tube. A cover 42 is mounted on the base 41 and has an inlet 421 which communicates with an interior of the base 41. A centrifugal fan 4 is eccentrically received in the base 41 and includes a blade unit 46 which is located corresponding to the through hole 411. The blade unit 46 is driven by a motor 44 which is enclosed by a bush 45 and connected to the blade unit 46.

A heat exchanging unit 5 has a plurality of fins 51 which are located around the centrifugal fan 4. A copper made heat exchanging tube 52 is engaged with the groove 411 of the base 41 and a heat exchangeable substance, such as water, is received in the heat exchanging tube 52. The heat exchanging tube 52 is vacuumed first and water is then filled into the heat exchanging tube 52. It is noted that the vaporization temperature and the due point of the water under lower pressure will be lowered so that the water can be easily vaporized by absorbing heat and then cooled down when the heat is removed. The heat exchanging tube 52 is a substantially horseshoe-shaped tube including two open ends 522 connected between an enclosed section 521. The enclosed section 521 is located higher than the two open ends 522 which extend out from the base 41 so as to be connected to a heat source such as a CPU or chip (not shown). The fins 51 are located to enclose the blade unit 46 and in contact with the heat exchanging tube 52.

When the heat form the heat source is transferred to the heat exchanging tube 52 from the two open ends of the heat exchanging tube 52, the water in the heat exchanging tube 52 is easily vaporized by absorbing heat and flow toward the enclosed section 521 which is located higher than the open ends 522. The heat is transferred to the fins 51 during the vaporized water moving toward the enclosed section 521. The blade unit 46 generates air flows to bring the heat out from the outlet 43. The vaporized water is then cooled when the heat is removed and then flows toward the open ends 522 again to absorb heat again. Therefore, the heat is exchanged during the movement of the different phases of the water in the heat exchanging tube 52. By this way, the heat of the heat source can be efficiently removed.

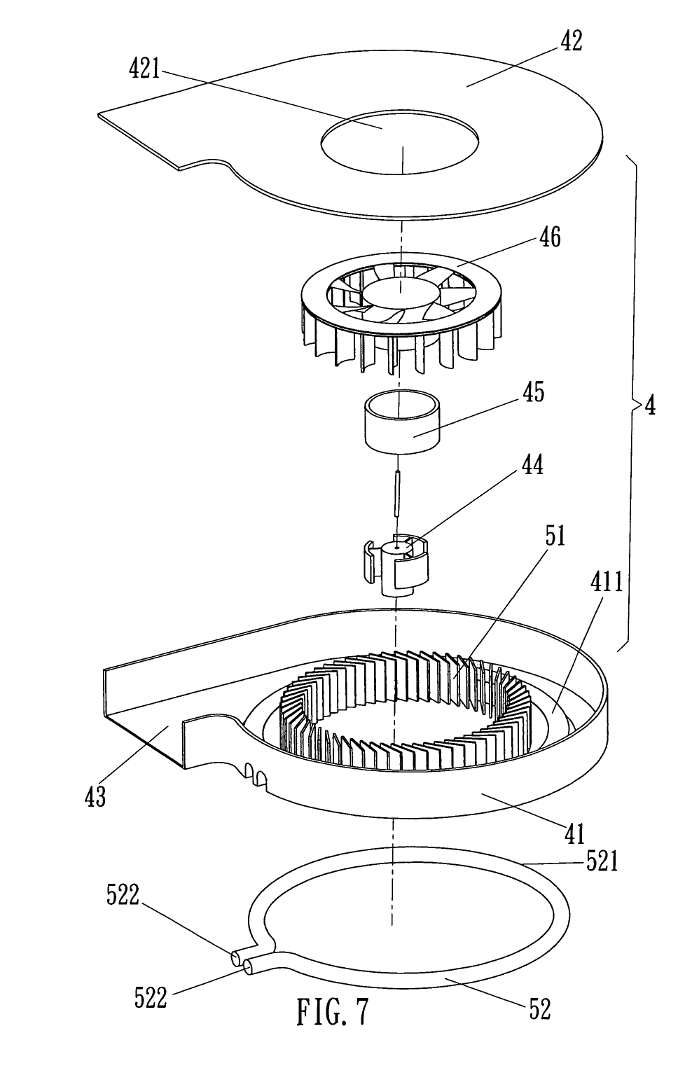

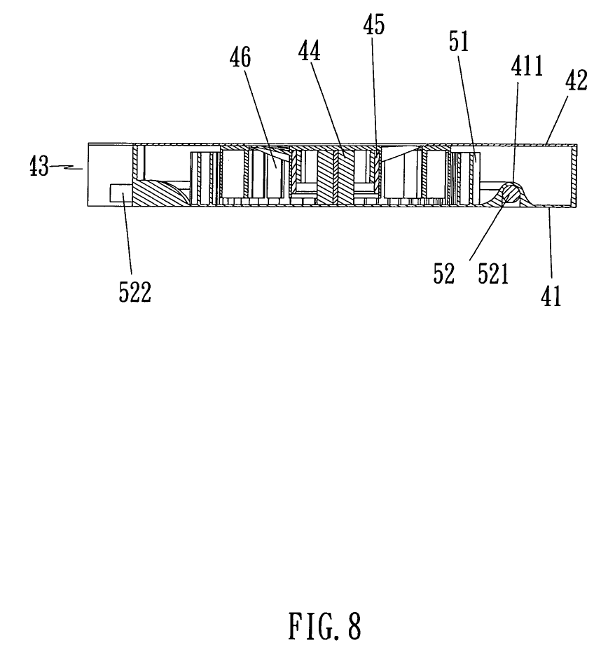

FIGS. 7 and 8 show another embodiment of the present invention, wherein the groove 411 is located such that the fins 51 are enclosed by the groove 411 with which the heat exchanging tube 52 is engaged. The heat absorbed by the heat exchanging tube 52 can be transferred to the fins 51 and brought by the air flows of the blade unit 46.

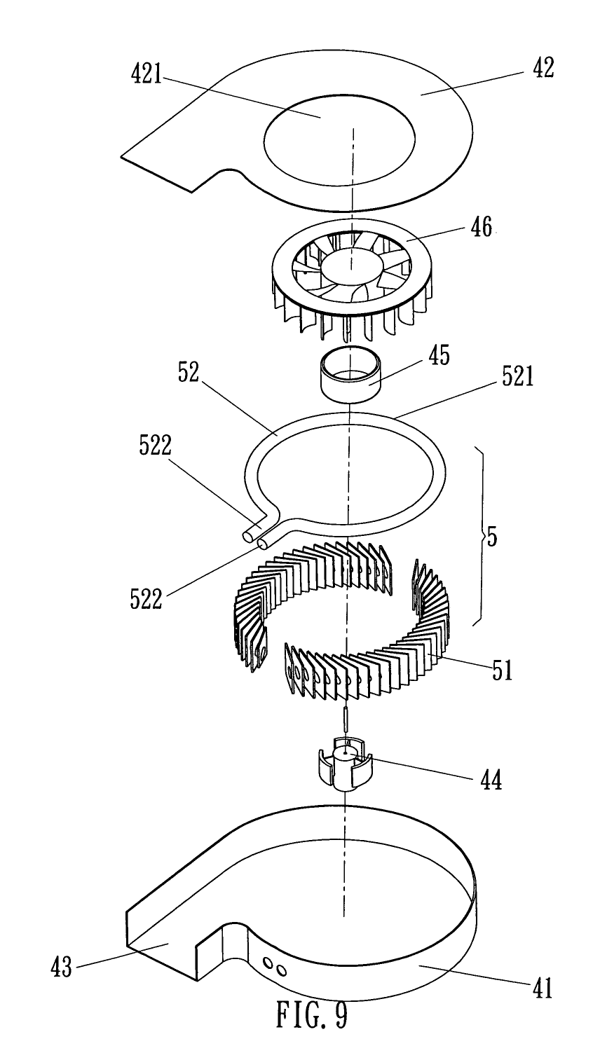

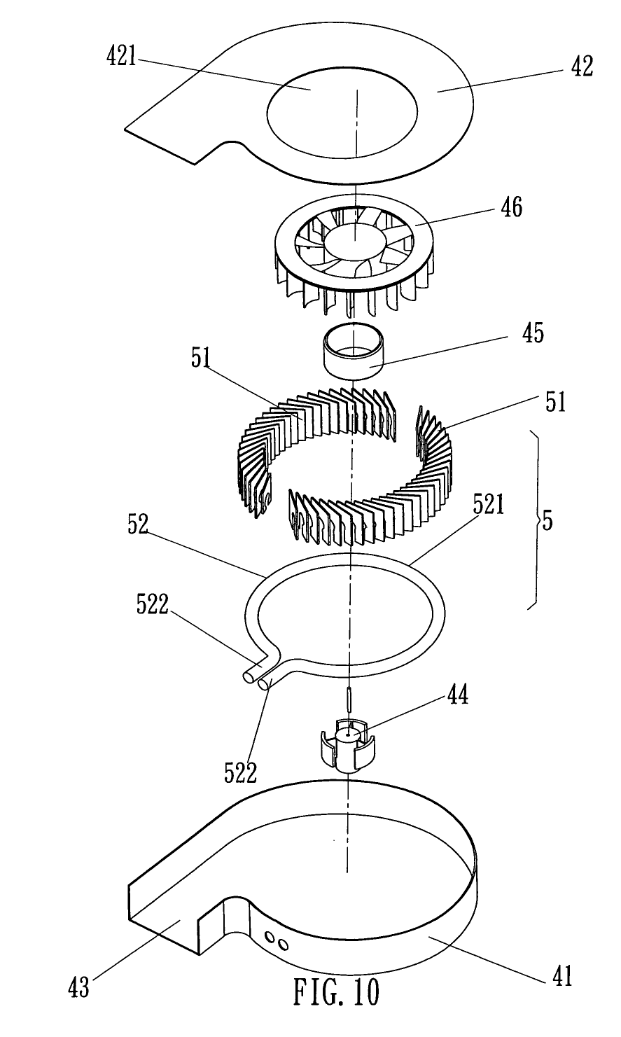

FIG. 9 shows that each of the fins 52 includes an aperture through which the heat exchanging tube 52 extends. FIG. 10 shows that each of the fins 52 may have a notch defined in an underside thereof and the heat exchanging tube 52 is engaged with the notches of the fins 52.

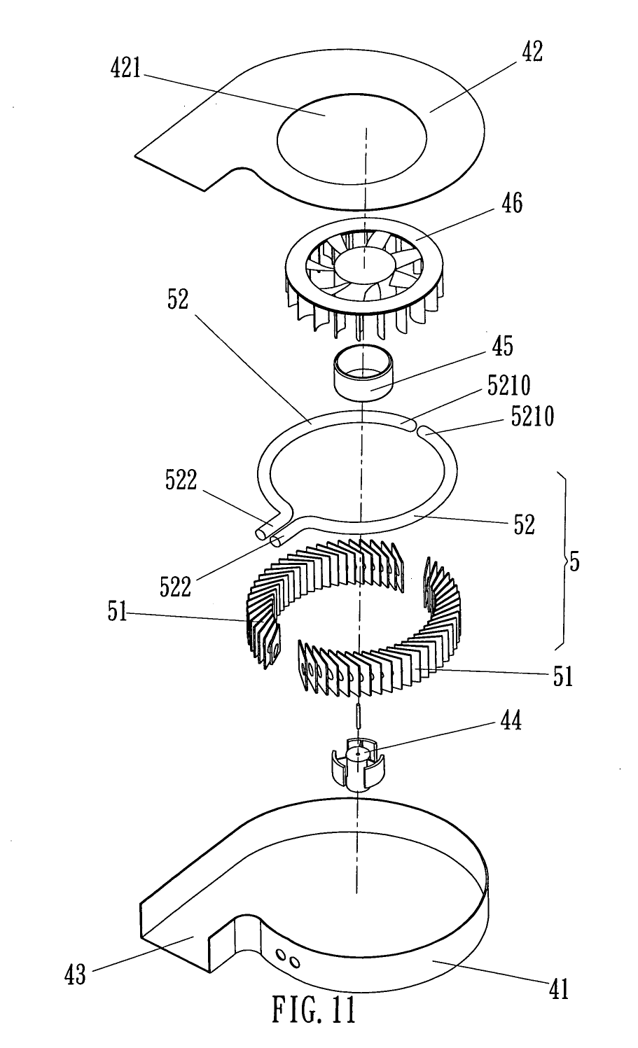

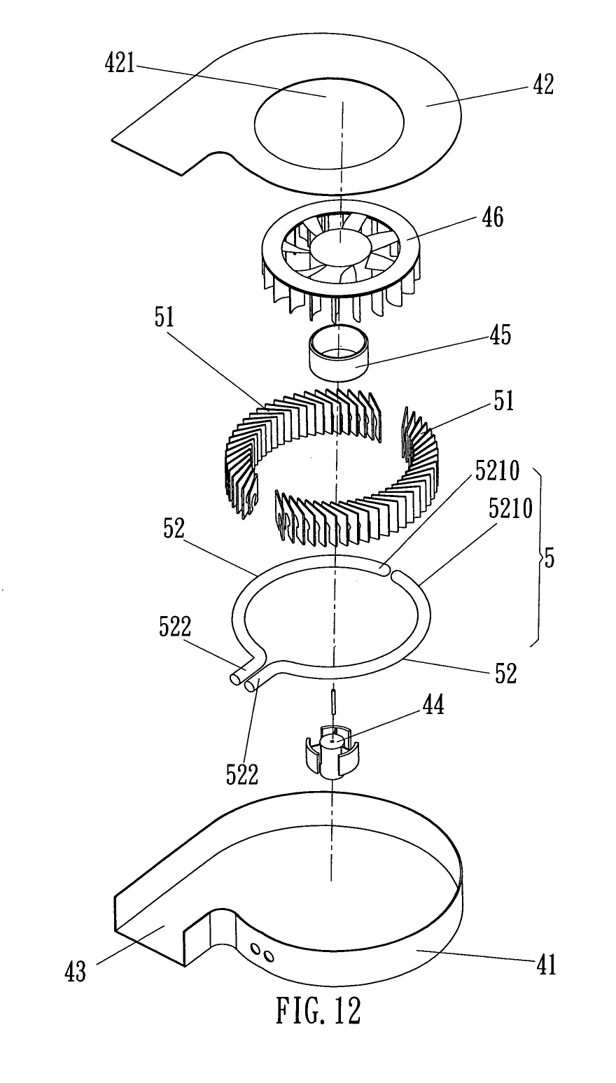

FIGS. 11 and 12 show that the heat exchanging tube 52 is composed of two parts and each part includes an open end 522 and a closed end 5210. The two parts of the heat exchanging tube 52 extend through the apertures in the fins 52 or are engaged with the notches in the fins 52.

The heat exchanging unit 5 is connected to the centrifugal fan 4 so that the whole heat dispensing assembly occupies only a small space and can be used in modern electronic appliances. The open ends 522 of the heat exchanging tube 52 are directly connected to the heat source and the enclosed section 521 is located higher than the open ends 522 so that the water in the heat exchanging tube 52 can easily flow and the heat can be moved efficiently.

While we have shown and described the embodiment in accordance with the present invention, it should be clear to those skilled in the art that further embodiments may be made without departing from the scope of the present invention.

What is claimed is:

1. A heat dispensing assembly comprising:
a base having an outlet defined in a side of the base, a cover mounted on the base and having an inlet defined therethrough, a centrifugal fan eccentrically received in the base and including a blade unit, and
a heat exchanging unit having a plurality of fins which are located around the centrifugal fan, a heat exchanging tube received in the base and a heat exchangeable substance received in the heat exchanging tube.

2. The assembly as claimed in claim 1, wherein the heat exchanging tube is a substantially horseshoe-shaped tube including two open ends connected between an enclosed section.

3. The assembly as claimed in claim 1, wherein an inner top surface of the base includes a groove with which the heat exchanging tube is engaged.

4. The assembly as claimed in claim 1, wherein the heat exchanging tube encloses the fins.

5. The assembly as claimed in claim 1, wherein each of the fins includes an aperture through which the heat exchanging tube extends.

6. The assembly as claimed in claim 1, wherein each of the fins includes a notch defined in an underside thereof and the heat exchanging tube is engaged with the notches of the fins.

7. The assembly as claimed in claim 2, wherein the two open ends of the heat exchanging tube extend out from the base.
